(19) United States
(12) Patent Application Publication
(10) Pub. No.: US 2024/0044360 A1
(43) Pub. Date: Feb. 8, 2024

(54) NOVEL HINGE AND INWARD-FOLDING FLEXIBLE SCREEN MOBILE TERMINAL

(71) Applicant: Hangzhou Amphenol Phoenix Telecom Parts Co., Ltd., Hangzhou (CN)

(72) Inventors: Qiangqiang ZHANG, Hangzhou (CN); Guoping YAO, Hangzhou (CN); Jiannan ZHANG, Hangzhou (CN); Xinhua WANG, Hangzhou (CN)

(21) Appl. No.: 18/262,876

(22) PCT Filed: Jan. 28, 2022
(86) PCT No.: PCT/CN2022/074811

§ 371 Date: Jul. 25, 2023

(30) Foreign Application Priority Data
Feb. 8, 2021 (CN) 202120372310.1

(51) Int. Cl. F16C 11/04; H05K 5/02

(52) U.S. Cl. CPC F16C 11/04; H05K 5/0226

(57) ABSTRACT

A novel hinge and an inward-folding flexible screen mobile terminal. Each of a left structure and a right structure of the hinge includes a mechanism consisting of a push-pull rod and a fixed base and used for pushing and pulling a housing connecting member to slidably move, a rotating member, a rotating guide rail, and a rotary supporting plate; the rotating member is slidably connected to the housing connecting member; the rotating guide rail is rotatably connected to the fixed base; the outer side end of the rotary supporting plate is a rotary connecting end and connected to the housing connecting member, and the rotary supporting plate is slidably connected to the rotating guide rail, so that the rotary supporting plate can rotate together with the housing connecting member, coaxially rotate with the rotating guide rail, and slide with respect to the rotating guide rail.

### FIELD OF THE INVENTION

The present invention relates to a hinge and an inward-folding flexible screen mobile terminal using the hinge.

### BACKGROUND OF THE INVENTION

Different measures are taken for a flexible screen mobile terminal to deal with the bulging shape of the bending part when the flexible screen is folded. A measure is to provide a rotating plate in the middle to avoid, so that the folded middle seam can be straight, and the folded middle part of the flexible screen is similar to a droplet shape. In order to realize the hinge structure with this measure, the narrow bezel design of the inward-folding flexible screen mobile terminal will be restricted.

### SUMMARY OF THE INVENTION

An object of the present invention is to provide a new technical solution for the problems existing in the background art, which can be applied to an inward-folding flexible screen mobile terminal, to realize the requirement for droplet-shaped avoidance, and meet the requirements of narrow bezel and thin shape of the mobile terminal. In order to achieve this object, the present invention adopts the following technical solutions:

A novel hinge, comprising a left structure and a right structure, wherein each of the left structure and the right structure comprises:

a mechanism consisting of a push-pull rod and a fixed base and used for pushing and pulling a housing connecting member to slidably move;

a rotating member, the rotating member is slidably connected to the housing connecting member, the sliding direction is perpendicular to the rotation axis of the rotating member, and the housing connecting member and the rotating member rotate around the same axis synchronously;

a rotating guide rail, the rotating guide rail is rotatably connected to the fixed base;

a rotary supporting plate, which is used to support the flexible screen at a position close to the middle part when the flexible screen mobile terminal is unfolded, and avoid the middle bulging part of the flexible screen when the flexible screen mobile terminal is in a folded state; the outer side end of the rotary supporting plate is a rotary connecting end and connected to the housing connecting member, and the rotary supporting plate is slidably connected to the rotating guide rail, so that the rotary supporting plate can rotate together with the housing connecting member, coaxially rotate with the rotating guide rail, and slide with respect to the rotating guide rail.

The hinge is a hinge applied in an inward-folding flexible screen mobile terminal.

Further, the housing connecting member is rotatably connected to the push-pull rod, and the push-pull rod is rotatably connected to the fixed base; the push-pull rod is rotatably connected to the fixed base by means of a structure of a circular arc sliding block and a circular arc guide rail, and the rotation axis is higher than the height of the back of the flexible screen when the flexible screen mobile terminal is unfolded.

Further, the rotary supporting plate is rotatably connected to the housing connecting member by means of a structure of a circular arc sliding block and a circular arc guide rail, and the rotation axis is higher than the height of the back of the flexible screen when the flexible screen mobile terminal is unfolded.

Another object of the present invention is to provide an inward-folding flexible screen mobile terminal using the hinge, which is capable of avoiding the drop-shaped bending part of the flexible screen and meet the requirements for narrow bezel and thin shape. To achieve the object, the present invention adopts the following technical solutions:

An inward-folding flexible screen mobile terminal is provided, comprising a left housing, a right housing and an inner flexible screen, wherein the inward-folding flexible screen mobile terminal further comprises the hinge, the housing connecting members of the left structure and the right structure are fixedly connected to the left housing and the right housing respectively, and the left housing and the right housing synchronously rotate and synchronously slide with the housing connecting members of the left structure and the right structure respectively; taking the unfolded state of the inward-folding flexible screen mobile terminal as a reference state, the rotating members of the left structure and the right structure, the rotary supporting plate, the mechanism used for pushing and pulling a housing connecting member to slidably move, and the rotating guide rail are arranged below the inner flexible screen; wherein, the fixed base is arranged in the middle housing between the left housing and the right housing, in the left structure, the rotation axis of the rotating guide rail is higher than the rotation axis of the rotating member, and is more to the left than the rotation axis of the rotating member, in the right structure, the rotation axis of the rotating guide rail is higher than the rotation axis of the rotating member, and is more to the right than the rotation axis of the rotating member.

Due to the adoption of the technical solutions herein, the present invention can be applied to an inward-folding flexible screen mobile terminal, which can meet the avoidance requirement of a droplet shape and narrow a bezel to the maximum extent; moreover, by means of the rotary supporting plate sliding together with the housing connecting member and the cooperation of a virtual rotating shaft, the structure is compact, and thus a thin design of the inward-folding flexible screen mobile terminal is facilitated.

### BRIEF DESCRIPTION OF THE DRAWINGS

FIG. 1 is an exploded view of a structure according to an embodiment of the present invention.

FIG. 2 is a front view of a partial structure of an inward-folding flexible screen mobile terminal in an unfolded state according to an embodiment of the present invention.

FIG. 3 is a front view of a partial structure of an inward-folding flexible screen mobile terminal in a folded state according to an embodiment of the present invention.

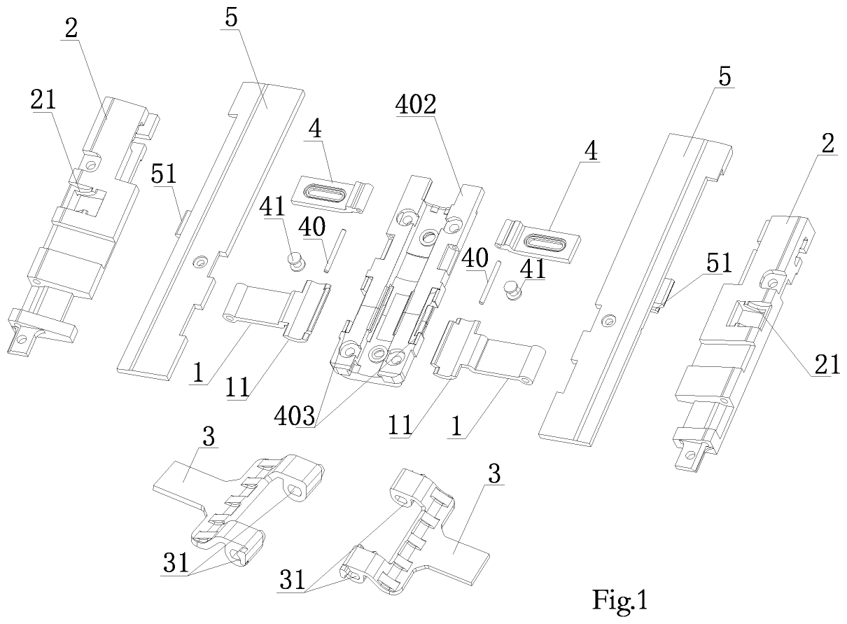

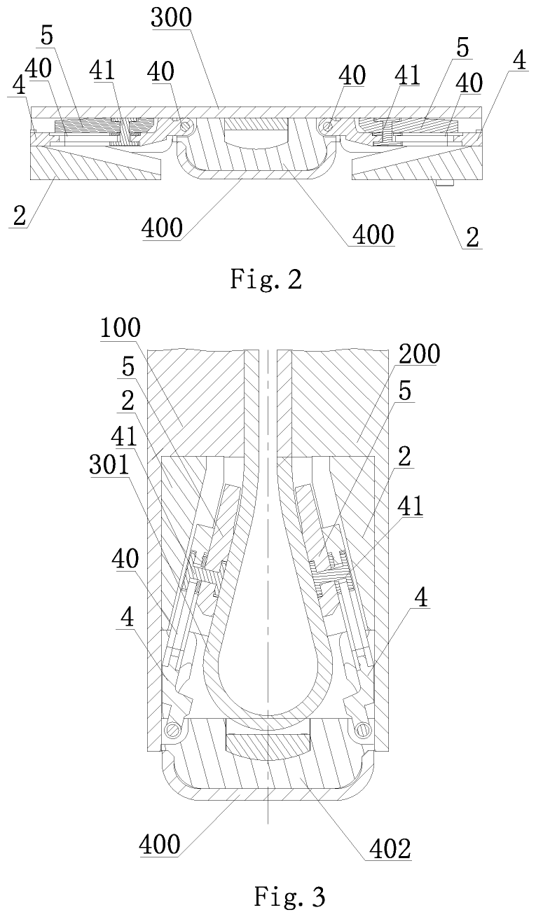

### DETAILED DESCRIPTION

Referring to the accompanying drawings, a hinge provided in the present invention comprises a left structure and a right structure, wherein the left structure and the right structure each comprise:

a mechanism consisting of a push-pull rod 1 and a fixed base 402 and used for pushing and pulling a housing connecting member 2 to slidably move, which is arranged below the inward-folding flexible screen 300 by taking an unfolded state of the inward-folding flexible screen mobile terminal as a reference state; When the inward-folding flexible screen mobile terminal rotates from the unfolded state to the folded state, the push-pull rod 1 pushes the housing connecting member 2 outwardly, and when the inward-folding flexible screen mobile terminal rotates from the folded state to the unfolded state, the push-pull rod 1 pulls the housing connecting member 2 inwardly;

a rotating member 3, which is arranged below the inward-folding flexible screen 300 by taking an unfolded state of the inward-folding flexible screen mobile terminal as a reference state; the rotating member 3 is slidably connected to the housing connecting member 2, and the sliding direction is perpendicular to the rotation axis of the rotating member 3; a sliding guide structure may be provided between the rotating member 3 and the housing connecting member 2, and the housing connecting member 2 and the rotating member synchronously rotate about the same axis, i.e. the housing connecting member 2 is a slidable and rotatable component. The inward-folding flexible screen mobile terminal comprises a left housing 100, a right housing 200 and an inner flexible screen 300, and the housing connecting members 2 of the left structure and right structure are fixedly connected to the left housing 100 and right housing 200 respectively, such that the left housing 100, the right housing 200 synchronously rotate and synchronously slide with the housing connecting members 2 of the left structure and the right structure respectively;

a rotating guide rail 4, the rotating guide rail is rotatably connected to the fixed base 402, and is the only rotatable component; the reference numeral 40 indicates its rotation axis; the rotating guide rail is arranged below the inward-folding flexible screen 300 by taking an unfolded state of the inward-folding flexible screen mobile terminal as a reference state. The shape of a guide groove in the rotating guide rail 4 can be a line groove, which is used for flexibly connecting to a rotatable connecting plate 5, such that only relative sliding occurs between the rotating guide rail 4 and the rotatable connecting plate 5 without changing the angle between them;

a rotary supporting plate 5, which is used to support the flexible screen 300 at a position close to the middle part when the inward-folding flexible screen mobile terminal is unfolded, and avoid the middle bulging part 301 of the flexible screen 300 by turning a certain angle and tilting when the flexible screen mobile terminal is in a folded state; the outer side end of the rotary supporting plate 5 is a rotary connecting end and connected to the housing connecting member 2, and the rotary supporting plate 5 is slidably connected to the rotating guide rail 4 (the rotary supporting plate 5 can be slidably connected to the rotating guide rail 4 by means of a rivet 41 that snaps into the guide groove in the rotating guide rail 4 and can slide), so that the rotary supporting plate can rotate together with the housing connecting member 2. When the housing connecting member 2 rotates, the rotary supporting plate moves around the axis of the housing connecting member 2 on the one hand, and on the other hand, rotates coaxially with the rotating guide rail 4 and slides with respect to the rotating guide rail 4. During the folding process of the inward-folding flexible screen mobile terminal, the housing connecting member 2 gradually leaves the middle housing 400 while sliding; when the inward-folding flexible screen mobile terminal is folded, a tilt angle is provided to enable the rotating guide rail to hang on the middle housing 400. The relationship between the rotary supporting plate 5 and the housing connecting member can be direct, i.e. the rotary supporting plate can be directly rotatably connected to the housing connecting member 2; or the relationship can be indirect; since the left housing 100 and the right housing 200 of the inward-folding flexible screen mobile terminal are fixed together with the housing connecting members 3 on the left side and the right side, the outer ends of the rotary supporting plates on the left and right sides can be rotatably connected to the left housing 100 and the right housing 200, or rotatably connected to other components fixed on the left housing 100 and the right housing 200, and components fixed on the housing connecting members 3 on the left side and the right side.

The outer side end of the rotary supporting plate 5 is rotatably connected to the housing connecting member 2 by means of a structure of a circular arc sliding block 51 and a circular arc guide rail 21, and the rotation axis is higher than the height of the back of the flexible screen when the inward-folding flexible screen mobile terminal is unfolded; with this virtual rotating shaft structure, a thin design is further facilitated.

Through the above structure, in fact, almost all the control structures related to the rotary supporting plate 5 are arranged below the flexible screen 300, such that the narrow bezel of the terminal product can be realized.

Returning to the mechanism that is used for pushing and pulling a housing connecting member 2 to slidably move, the housing connecting member 2 is rotatably connected to the push-pull rod 1, and the push-pull rod 1 is rotatably connected to the fixed base 402; the fixed base 402 is fixed in the middle housing 400. The push-pull rod 1 is rotatably connected to a fixed base 402 by means of a structure of a circular arc sliding block 11 and a circular arc guide rail 403, and the rotation axis is higher than the height of the back of the flexible screen when the inward-folding flexible screen mobile terminal is unfolded. With this virtual rotating shaft structure, the following axis arrangement can be more easily realized without limiting the thickness of the inward-folding flexible screen mobile terminal: in the left structure, the rotation axis of the rotating guide rail 4 is higher than the rotation axis of the rotating member 3 but is lower than the axis of rotation connection between the push-pull rod 1 and the fixed base 402, and is more to the left than the rotation axis of rotating member 3 (the reference numeral 31 represents its shaft hole) and the axis of rotation connection between the push-pull rod 1 and the fixed base 402; in the right structure, the rotation axis of the rotating guide rail 4 is higher than the rotation axis of the rotating member 3 but is lower than the axis of the rotation connection between the push-pull rod 1 and the fixed base 402, and is more to the right than the rotation axis of the rotating member 3 and the axis of rotation connection between the push-pull rod 1 and the fixed base 402.

The fixed base part connected to the rotating guide rail 4 and the fixed base part connected to the push-pull rod 1 can be integrated or split.

The hinge also comprises a synchronous reverse rotation connection structure, which is connected between the left structure and the right structure, such that the rotating members 3 of the left structure and the right structure rotate synchronously and reversely; and the synchronous reverse rotation connection structure is arranged in the middle housing 400. Thus, the left housing 100 and the right housing 200 also rotate synchronously and reversely. The synchronous reverse rotation connection structure may adopt a gear meshing connection structure. In the hinge, the rotating member 3 may be connected to the synchronous reverse rotation connection structure.

The description only describes the specific embodiments of the present invention, but the structural features of the present invention are not limited thereto. Any changes or modifications made by those skilled in the art within the field of the present invention shall fall within the scope of protection of the present invention.

It should be noted that the terms “comprising” and “having” in the description and claims of the present invention and the accompanying drawings, as well as any modifications thereof, are intended to cover non-exclusive inclusion. The terms “installed/mounted”, “arranged”, “set”, “connected”, “sleeved” should be construed broadly. For example, it may be a fixed connection, a detachable connection, or an integral structure; it may be a mechanical connection, or an electrical connection; it may be directly connected, or indirectly connected through an intermediary, or between two devices, elements, or internal communication between components. For those of ordinary skill in the art, the specific meanings of the above terms in the present invention can be understood according to specific situations.

It should be understood that, in the description of the present invention, the orientation or positional relationship indicated by the terms “one end”, “another end”, “outside”, “inside”, “horizontal”, “end”, “length”, “outer end”, “left”, “right”, etc. is based on the orientation or positional relationship shown in the figures, and is only for the convenience of describing the present invention and simplifying the description, rather than indicating or implying that the indicated device or element must have the particular orientation, construction and operation in the particular orientation, therefore, it cannot be construed as limitations of the present invention. The terms “first”, “second” are used for brevity of description only, and do not indicate or imply relative importance.

1. A novel hinge, comprising a left structure and a right structure, wherein each of the left structure and the right structure comprises:
a mechanism consisting of a push-pull rod and a fixed base and used for pushing and pulling a housing connecting member to slidably move;
a rotating member, the rotating member is slidably connected to the housing connecting member, the sliding direction is perpendicular to the rotation axis of the rotating member, and the housing connecting member and the rotating member rotate around the same axis synchronously;
a rotating guide rail, the rotating guide rail is rotatably connected to the fixed base;
a rotary supporting plate, which is used to support the flexible screen at a position close to the middle part when the flexible screen mobile terminal is unfolded, and avoid the middle bulging part of the flexible screen when the flexible screen mobile terminal is in a folded state; the outer side end of the rotary supporting plate is a rotary connecting end and connected to the housing connecting member, and the rotary supporting plate is slidably connected to the rotating guide rail, so that the rotary supporting plate can rotate together with the housing connecting member, coaxially rotate with the rotating guide rail, and slide with respect to the rotating guide rail.

2. The novel hinge according to claim 1, wherein the hinge is a hinge applied in an inward-folding flexible screen mobile terminal.

3. The novel hinge according to claim 1, wherein the housing connecting member is rotatably connected to the push-pull rod, and the push-pull rod is rotatably connected to the fixed base;
the push-pull rod is rotatably connected to the fixed base by means of a structure of a circular arc sliding block and a circular arc guide rail, and the rotation axis is higher than the height of the back of the flexible screen when the flexible screen mobile terminal is unfolded.

4. The novel hinge according to claim 1, wherein the rotary supporting plate is rotatably connected to the housing connecting member by means of a structure of a circular arc sliding block and a circular arc guide rail, and the rotation axis is higher than the height of the back of the flexible screen when the flexible screen mobile terminal is unfolded.

5. An inward-folding flexible screen mobile terminal, comprising a left housing, a right housing and an inner flexible screen, wherein the inward-folding flexible screen mobile terminal further comprises the hinge of claim 1, the housing connecting members of the left structure and the right structure are fixedly connected to the left housing and the right housing respectively, and the left housing and the right housing synchronously rotate and synchronously slide with the housing connecting members of the left structure and the right structure respectively;
taking the unfolded state of the inward-folding flexible screen mobile terminal as a reference state, the rotating members of the left structure and the right structure, the rotary supporting plate, the mechanism used for pushing and pulling a housing connecting member to slidably move, and the rotating guide rail are arranged below the inner flexible screen; wherein, the fixed base is arranged in the middle housing between the left housing and the right housing, in the left structure, the rotation axis of the rotating guide rail is higher than the rotation axis of the rotating member, and is more to the left than the rotation axis of the rotating member, in the right structure, the rotation axis of the rotating guide rail is higher than the rotation axis of the rotating member, and is more to the right than the rotation axis of the rotating member.
